(19) United States
(12) Patent Application Publication
(10) Pub. No.: US 2021/0202818 A1
(43) Pub. Date: Jul. 1, 2021

(54) FLEXIBLE THERMOELECTRIC DEVICES

(71) Applicant: 3M INNOVATIVE PROPERTIES COMPANY, St. Paul, MN (US)

(72) Inventors: Ravi Palaniswamy, Choa Chu Kang (SG); Donato G. Caraig, Choa Chu Kang (SG); Jian Xia Gao, Jurong West (SG); Alejandro Aldrin A. Narag, II, Choa Chu Kang (SG); Siang Sin Foo, Sin Ming Walk (SG); Antonny E. Flor, Sembawang (SG)

(21) Appl. No.: 16/948,395

(22) PCT Filed: Mar. 14, 2019
(86) PCT No.: PCT/IB2019/052098

§ 371 Date: Sep. 16, 2020

Related U.S. Application Data
(60) Provisional application No. 62/649,226, filed on Mar. 28, 2018.

(51) Int. Cl. H01L 35/32; H01L 35/34

(52) U.S. Cl. CPC H01L 35/32; H01L 35/34

(57) ABSTRACT

Flexible thermoelectric devices including an array of slot openings on a flexible substrate, and methods of making and using the same are provided. The slot openings on the flexible substrate can help remove the tension or compression induced during bending of the devices. Slot openings each extend along a cross direction substantially perpendicular to the longitudinal direction of the substrate.

### TECHNICAL FIELD

The present disclosure relates to flexible thermoelectric devices including an array of slot openings on a flexible substrate, and methods of making and using the same.

### BACKGROUND

Thermoelectric devices have been widely used for heating or cooling. One commercial thermoelectric device was made by sandwiching thermoelectric elements with ceramic printed circuit boards (PCBs).

### SUMMARY

The present disclosure provides a flexible thermoelectric device including an array of slot openings on a flexible substrate, and methods of making and using the same.

In one aspect, the present disclosure describes a thermoelectric device including a flexible substrate having opposite first and second sides, the flexible substrate extending along a longitudinal direction; a first set of electrodes on the first side of the flexible substrate; a second set of electrodes on the second side of the flexible substrate; and an array of thermoelectric elements supported by the flexible substrate. The plurality of thermoelectric elements are electrically connected by the first set of electrodes on the first side and the second set of electrodes on the second side. The flexible substrate has an array of slot openings each extending along a cross direction substantially perpendicular to the longitudinal direction.

In another aspect, the present disclosure describes a method of making a thermoelectric device. The method includes providing a web path to move the web along a machine direction, the web having opposite first and second side; providing a patterned electrode on the first side of the web; creating an array of slots on the first surface of the web, each extending along a cross direction substantially perpendicular to the machine direction; and providing a plurality of thermoelectric elements supported by the web. The plurality of thermoelectric elements are electrically connected by the patterned electrode on the first side.

In some embodiments, the photoresist pattern is created by a photolithography process. The photolithography process includes providing a plurality of regions on the web arranged along the machine direction thereof, each region including a plurality of registration through holes configured to align patterns on the opposite first and second sides. The photolithography process further includes providing a plurality of photomasks to develop the plurality of regions of the web, respectively. The plurality of photomasks each include first registration marks to align with each other, and second registration marks to align with the web.

Various unexpected results and advantages are obtained in exemplary embodiments of the disclosure. One such advantage of exemplary embodiments of the present disclosure is that an array of slot openings on a flexible substrate can help remove the tension or compression induced during bending of a thermoelectric device described herein. In addition, a photolithography process described herein can fabricate a flexible thermoelectric device having a remarkable length (e.g., about 1-2 meters).

Various aspects and advantages of exemplary embodiments of the disclosure have been summarized. The above Summary is not intended to describe each illustrated embodiment or every implementation of the present certain exemplary embodiments of the present disclosure. The Drawings and the Detailed Description that follow more particularly exemplify certain preferred embodiments using the principles disclosed herein.

### BRIEF DESCRIPTION OF THE DRAWINGS

The disclosure may be more completely understood in consideration of the following detailed description of various embodiments of the disclosure in connection with the accompanying figures, in which:

FIG. 1A illustrates a schematic cross-sectional view of a photoresist pattern disposed on a flexible substrate having an electrically conductive layer, according to one embodiment.

FIG. 1B illustrates a schematic cross-sectional view of the flexible substrate of FIG. 1A, where metal circuits were grown up, according to one embodiment.

FIG. 1C illustrates a schematic cross-sectional view of the flexible substrate of FIG. 1C, where via holes are formed thereon, according to one embodiment.

FIG. 1D illustrates a schematic cross-sectional view of the flexible substrate of FIG. 1C, where an electrode pattern is formed thereon, according to one embodiment.

FIG. 1E illustrates a schematic cross-sectional view of the flexible substrate of FIG. 1D, where an array of thermoelectric elements are received by the via holes, according to one embodiment.

FIG. 1F illustrates a schematic cross-sectional view of the flexible substrate of FIG. 1E, where a second set of electrodes are provided on the opposite side, according to one embodiment.

FIG. 1G illustrates a schematic cross-sectional view of the flexible substrate of FIG. 1F, where an array of slot openings is formed thereon, according to one embodiment.

FIG. 2A illustrates a photolithography process for making a photoresist pattern on a moving web, according to one embodiment.

FIG. 2B illustrates a process for making a thermoelectric device with an extended length, according to one embodiment.

FIG. 3A illustrates a schematic cross-sectional view of a top flexible circuit, according to one embodiment.

FIG. 3B illustrates a schematic cross-sectional view of a bottom flexible circuit, according to one embodiment.

FIG. 3C illustrates a schematic cross-sectional view of a flexible thermoelectric device by assembling the top and bottom flexible circuits of FIGS. 3A-B with an array of thermoelectric elements, according to one embodiment.

FIG. 3D is a top view of a portion of the flexible thermoelectric device of FIG. 3C.

FIG. 3E is a schematic cross-sectional view of the flexible thermoelectric device of FIG. 3C having a layer of thermal interface material (TIM), according to one embodiment.

FIG. 4 is a schematic cross-sectional view of the flexible thermoelectric device of FIG. 3E disposed on a curved surface, according to one embodiment.

In the drawings, like reference numerals indicate like elements. While the above-identified drawing, which may not be drawn to scale, sets forth various embodiments of the present disclosure, other embodiments are also contemplated, as noted in the Detailed Description. In all cases, this disclosure describes the presently disclosed disclosure by way of representation of exemplary embodiments and not by express limitations. It should be understood that numerous other modifications and embodiments can be devised by those skilled in the art, which fall within the scope and spirit of this disclosure.

### DETAILED DESCRIPTION

The present disclosure describes flexible thermoelectric devices including an array of slot openings on a flexible substrate, and methods of making and using the same. The slot openings on the flexible substrate can help remove the tension or compression induced during bending of the thermoelectric device described herein. In addition, a photolithography process described herein can fabricate a flexible thermoelectric device having a remarkable length (e.g., about 1 to 2 meters).

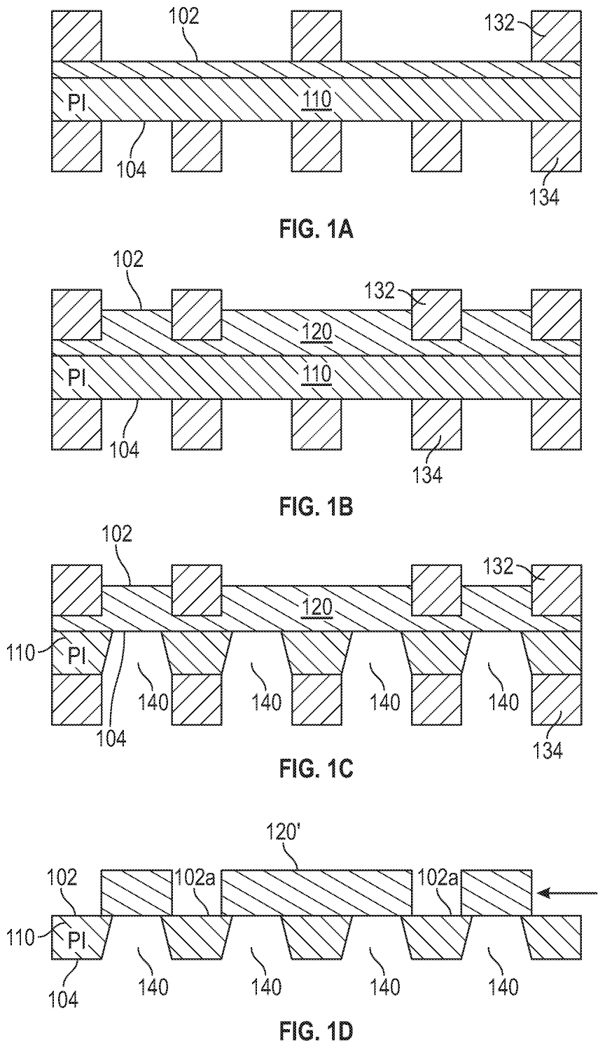

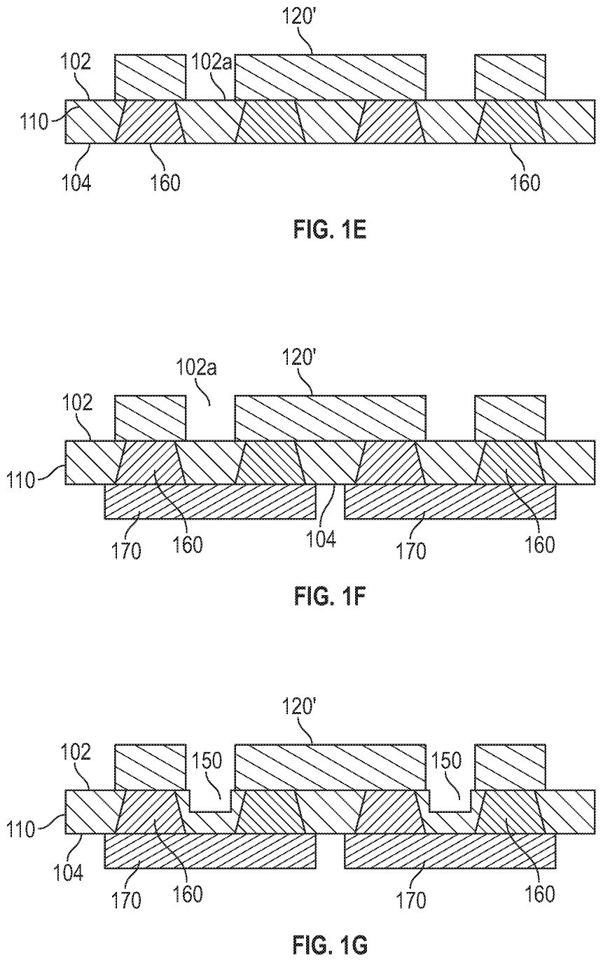

FIGS. 1A-E illustrate a process of making flexible thermoelectric devices described herein, according to some embodiments. In FIG. 1A, an electrically conductive layer 120 is provided on a first side 102 of a flexible substrate 110. The substrate 110 may be a flexible substrate made of any suitable materials such as, for example, polyimide, polyester, liquid crystalline polymer (LCP), polyamide, thermoplastic polyimide, thermoplastic dielectric film, polytetrafluoroethylene, perfluoroalkoxy alkane (PFA), etc. The electrically conductive layer 120 can include any suitable electrically conductive materials such as, metals, metal alloys, conductive inks, etc. In some embodiments, the electrically conductive layer 120 can be a Cu layer. A first photoresist pattern 132 is provided on the electrically conductive layer 120 to develop an electrode pattern on the first side 102. A second photoresist pattern 134 is provided on the second side 104 of the flexible substrate 110 to develop via holes on the second side 104.

In the depicted embodiment of FIG. 1B, the electrically conductive layer 120 is grown up such that the first photoresist pattern 132 is partially embedded in the electrically conductive layer 120. The electrically conductive layer 120 can be grown up by any suitable processes such as, for example, a copper plating process. In FIG. 1C, via holes 140 are created on the second side 104 of the flexible substrate 110. The via holes 140 are through-holes extending through the flexible substrate 110 to reach the back side of the electrically conductive layer 120. In some embodiments, the via holes 140 can be made by a chemical etching process. In FIG. 1D, the first and second photoresist patterns 132 and 134 are stripped off Then, the electrically conductive layer 120 is removed, e.g., by a flash etching process, from a non-functional area 102a of the substrate 110 to form an electrode pattern 120′. The via holes 140 are configured to receive at least a portion of thermoelectric elements, which is to be electrically connected in series by the electrode pattern 120′ on the first side 102.

As shown in FIG. 1E, an array of thermoelectric elements 160 are received by the via holes 140. In the depicted embodiment, the thermoelectric elements 160 include p-type thermoelectric elements and n-type thermoelectric elements that are electrically connected by the electrode pattern 120′ on the first side 102 of the substrate 110. In some embodiments, the thermoelectric elements 160 may be formed by disposing (e.g., printing, dispensing, etc.)

thermoelectric materials onto the substrate 110. In some embodiments, the thermoelectric elements 160 may be provided in the form of thermoelectric solid chips. The p-type thermoelectric elements may be made of a p-type semiconductor material such as, for example, Sb₂Te₃ or its alloys. The n-type thermoelectric elements may be made of an n-type semiconductor material such as, for example, Bi₂Te₃ or its alloys. Exemplary thermoelectric sensor modules and methods of making and using the same are described in U.S. Patent Application No. 62/353,752 (Lee et al.), which is incorporated herein by reference.

As shown in FIG. IF, the thermoelectric elements 160 are electrically connected by a second electrode pattern 170 formed on the second side 104 of the substrate 110. The first electrode pattern 120′ on the first side 102 and the second electrode pattern 170 on the second side 104 can electrically connect the thermoelectric elements 160 in series. The second electrode pattern 170 can be formed by any suitable processes such as, for example, a coating process. In some embodiments, the second electrode pattern may be formed by a Ag paste coating process.

As shown in FIG. 1G, an array of slot openings 150 are provided on the first side 102 of the substrate 110. The slot openings 150 can be made by any suitable processes such as, for example, chemical etching, mechanical punching, laser cutting, etc. In some embodiments, the slot openings 150 can be formed on the non-functional area 102a between the first electrode patterns 120′ as shown in FIG. 1D. In some embodiments, the slot openings 150 each can extend along a cross direction substantially perpendicular to the longitudinal direction of the substrate 110. In some embodiments, the slot openings 150 may partially extend into the substrate, having a depth D that is, for example, about 10% to about 90% of the thickness of the substrate 110. In some embodiments, the slot openings 150 can be through-holes that extends completely through the substrate 110 to reach the second side 104. In some embodiments, the slot openings 150 may have a slot width in a range of, for example, from about 50 micrometers to about 2 mm.

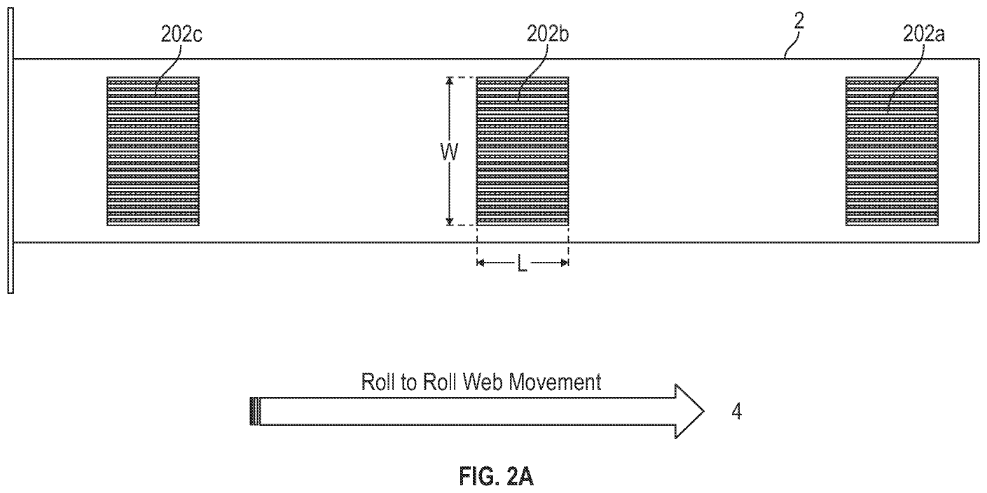

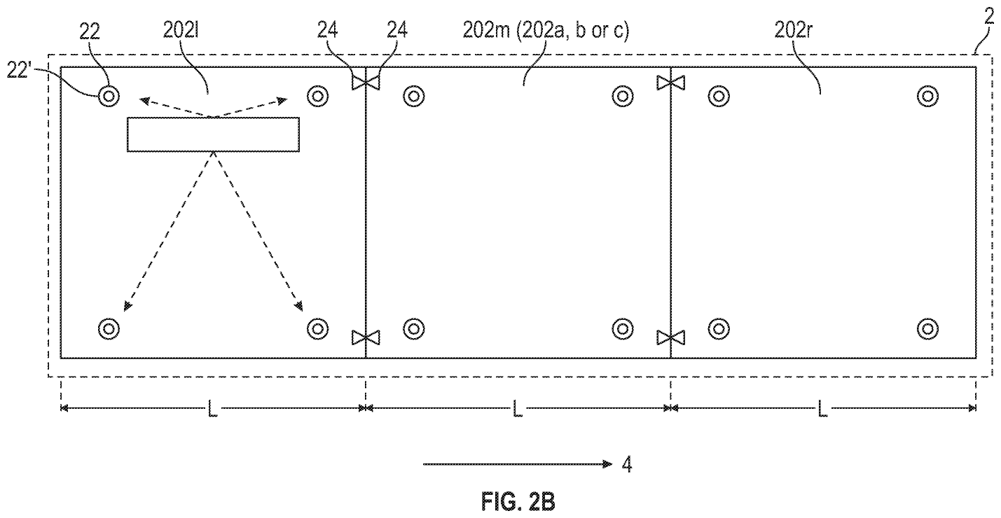

FIG. 2A illustrates a photolithography process for making a repeated photoresist pattern on a moving web, according to one embodiment. In a roll-to-roll process, a web of material 2 with an infinite length is moved along a longitudinal or machine direction 4. A first photoresist pattern frame is repeatedly formed on the web 2 as frames 202a , 202b and 202c , separated from each other with a fixed distance therebetween. The first photoresist pattern frame can be formed by passing the web 2 with a photoresist layer through an exposure system where a geometric pattern is transferred from a photomask to the photoresist layer on the web surface. The first photoresist pattern frame can be a portion of the photoresist pattern 132 on the first side 102 of the substrate 110 or a portion of the photoresist pattern 134 on the second side 104 in FIG. 1A. The first photoresist pattern frame may have an area (W×L) which corresponds to an exposure area of the exposure system. In some embodiments, the length L of the exposure area is limited by the exposure system in the range, for example, no more than about 300 mm, no more than about 400 mm, or no more than about 500 cm. In one exemplary exposure system, the length L of the exposure area is about 340 mm.

When thermoelectric devices are made on the web 2, the length of the thermoelectric devices may be limited by the length L of the exposure area of the exposure system. FIG. 2B illustrates a process for making a thermoelectric device with an extended length by aligning multiple photoresist pattern frames on the moving web, according to one embodiment. After the formation of a series of first photoresist pattern frames 202a , 202b and 202c separate from each other, multiple frames can be formed adjacent to the respective first frames, aligned with each other along the machine direction 4 to form a single thermoelectric device. In the embodiment depicted in FIG. 2B, the middle frame 202m can be one of the first frames 202a , 202b or 202c . Then a left frame 202l and a right frame 202r can be sequentially formed adjacent to the middle frame 202m . The left, middle, and right frames are aligned with each other. The patterns of the left, middle and right frames can be transferred from their respective photomasks. It is to be understood that the sequence of forming the frames may be varied.

The left, middle, and right frames each include registration marks 24 to align with each other. In the depicted embodiment of FIG. 2B, the middle frame 202m has four registration marks 24 on the left and right edges, which are aligned with the registration marks 24 on the edges of the left and right photomasks, respectively. In this manner, multiple frames can be formed on the same side of the substrate, aligned along the longitudinal or machine direction of the substrate. It is to be understood that the number of registration marks, the shape of the registration masks, the location of the registration masks on the respective frames can be determined according to desired applications.

FIG. 2B also illustrates how to align patterns on opposite side of the substrate 2 for the frames, according to one embodiment. In the regions of the substrate 2 having the multiple frames (e.g., the left, middle and right frames), each region is provided with registration through-holes 22. The respective patterns on the opposite sides each include registration marks 22′ to be aligned with the respective through-holes 22 on the substrate 2 such that the patterns on opposite sides of the substrate 2 can be aligned with each other. For example, the photoresist patterns 132 on the first side 102 and the photoresist pattern 134 on the second side 104 of the substrate (as shown in FIG. 1C) can be precisely aligned via the registration marks.

A single thermoelectric device can be formed on the multiple frames aligned along the longitudinal direction on both sides of the substrate. Each frame has a first set of electrodes and the second set of electrodes, the first sets are connected on the first side of the substrate, and the second sets are connected on the second side of the substrate. For example, as shown in FIG. 2B, the left, middle, and right frames 202l , 202m and 202r each include sets of electrodes, and the sets of electrodes can be connected such that the adjacent frames can form a single thermoelectric device having an extended length (e.g., 3×L). The thermoelectric device can have an extended length n×L, where n is the number of aligned frames. In some embodiments, the number n can be, for example, 2, 3, 4, or 5 according desired applications. In one exemplary embodiment, a single frame exposure can provide a device length of about 340 mm, and three-frame length can produce about 1 meter long for a typical application.

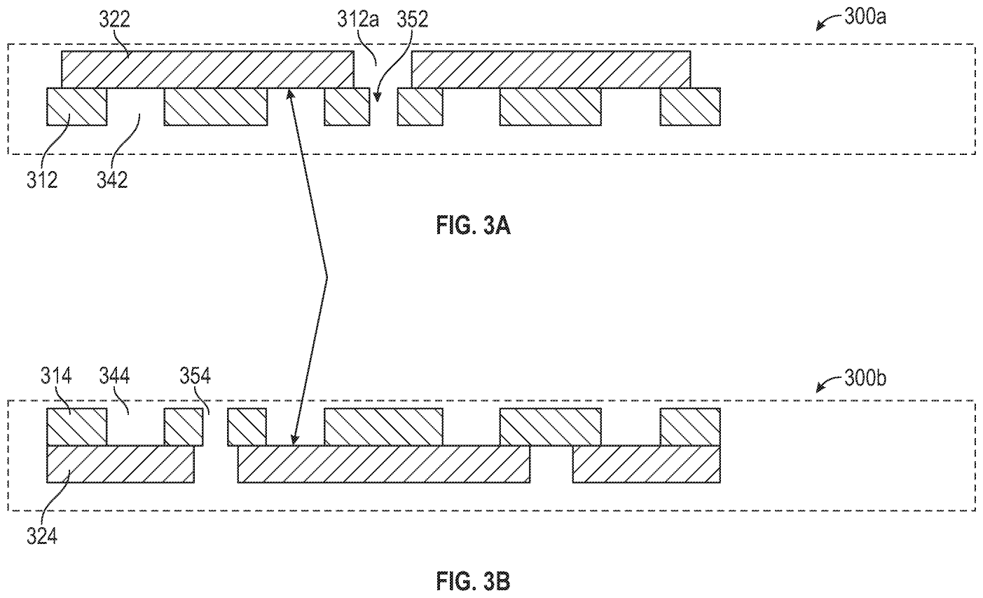

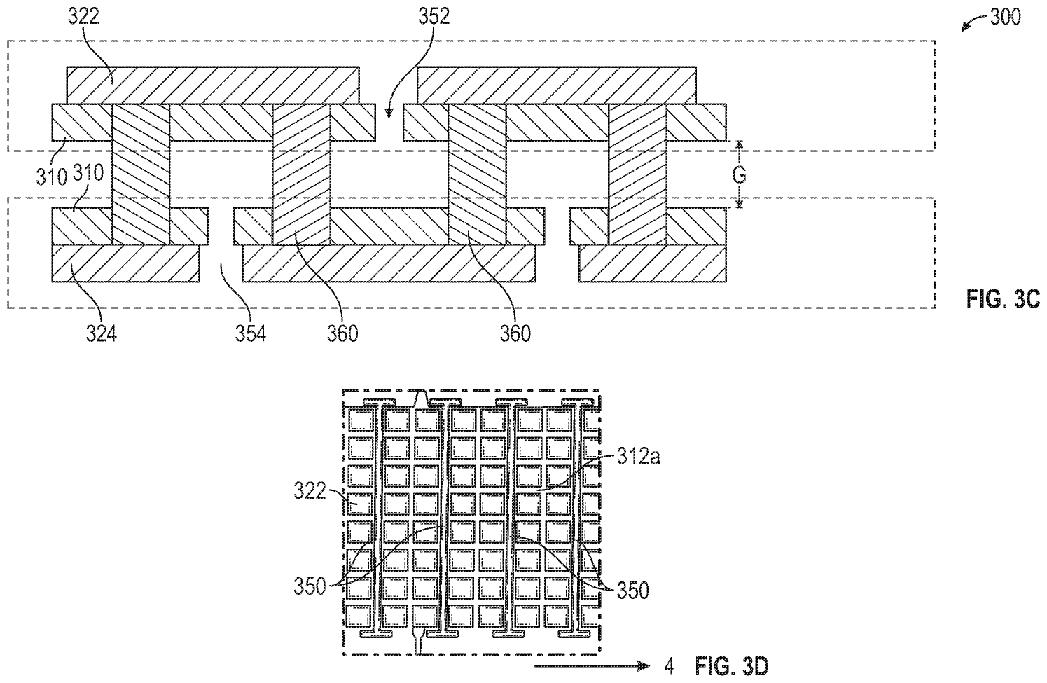

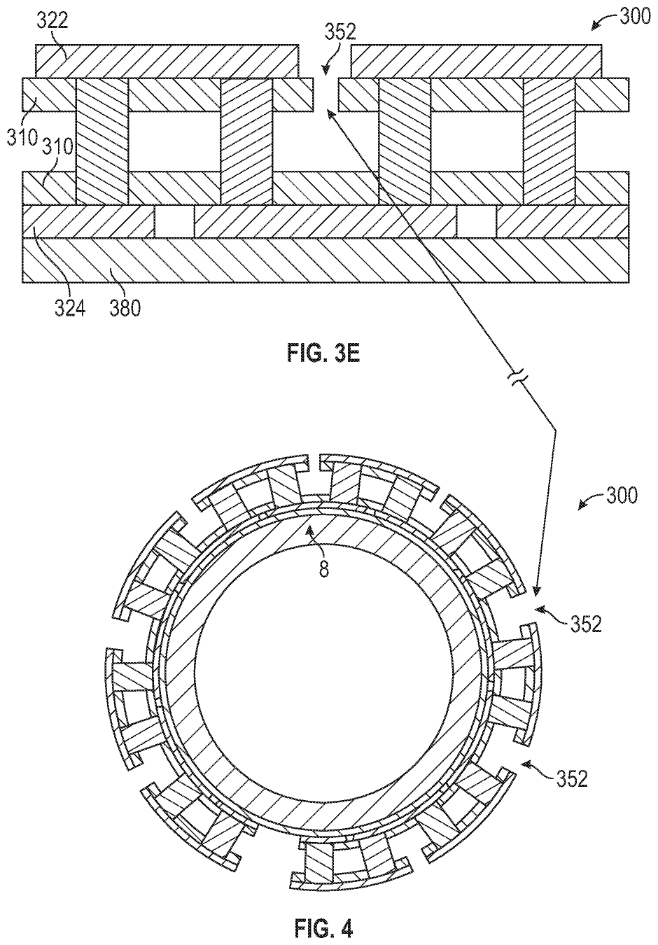

In some embodiments, a flexible thermoelectric device described herein may include a first flexible circuit having a first set of electrodes and a second flexible circuit having a second set of electrodes. An array of thermoelectric elements can be sandwiched between the top and bottom flexible circuits and electrically connected in series via the electrodes. FIG. 3A illustrates a schematic cross-sectional view of a first flexible circuit 300a , according to one embodiment. FIG. 3B illustrates a schematic cross-sectional view of a second flexible circuit 300b , according to one embodiment.

As shown in FIG. 3A, the first flexible circuit 300a is supported by a first flexible substrate 312. A first set of electrodes 322 is disposed on one side, and via holes 342 are formed from the opposite side to reach the electrodes 322. Slot openings 352 are formed on the first flexible substrate 312, among the gaps between the electrodes 322. The slot openings 352 can be through-openings extending across the first substrate 312. As shown in FIG. 3B, the second flexible circuit 300b is supported by a second flexible substrate 314. A second set of electrodes 324 is disposed on one side, and via holes 344 are formed from the opposite side to reach the electrodes 324. Slot openings 354 are formed on the second flexible substrate 314, among the gaps between the electrodes 324. In some embodiments, the second flexible substrate may not have the slot openings 354. The flexible substrate may have the same or different materials of the substrate 110 of FIG. 1A. It is to be understood that the first and second flexible circuits 300a and 300b each can be made by using the process of FIGS. 2A-B to achieve extended lengths.

FIG. 3C illustrates a schematic cross-sectional view of a flexible thermoelectric device 300 by assembling the first and second flexible circuits of FIGS. 3A-B with an array of thermoelectric elements 360, according to one embodiment. The thermoelectric elements 360 have one ends received by the via holes 342 of the first substrate 312, and the other ends received by the via holes 344 of the second substrate 314 (see also FIGS. 3A-B). Vertical or via conductors (e.g., solder) can be used to electrically connect the respective ends of the thermoelectric elements 360 to the first set of electrodes 322 on one side and the second set of electrodes 324 on the other side. In this manner, the first and second flexible circuits can be laminated to form the flexible thermoelectric device 300. In some embodiments, the first or second substrate may have a thickness, for example, from about 12.5 to about 100 micrometers. The gap G between the first or second substrate may depend on the thickness of thermoelectric element, for example, in a range from about 50 micrometers to about 1.5 mm.

FIG. 3D is a top view of a portion of the flexible thermoelectric device of FIG. 3C. The array of slot openings 352 is formed on the exposed area 312a of the flexible substrate, among the gaps between the electrodes 322. The slot openings 352 each extend in a cross-web direction, i.e., a direction substantially perpendicular to the longitudinal or machine direction 4. In some embodiment, some elements of the thermoelectric device (e.g., thermoelectric elements, electrodes, etc.) can be rigid. When the thermoelectric device is bent, undesired local tension or compression can be introduced. The slot openings 352 can help to remove such tension or compression induced, increasing the flexibility of the thermoelectric device.

FIG. 3E is a schematic cross-sectional view of the flexible thermoelectric device of FIG. 3C having a layer 380 of thermal interface material (TIM), according to one embodiment. The TIM layer 380 is provided to cover one or both sides of the thermoelectric device 300. The thermal interface material may include one or more pressure-sensitive adhesive (PSA) based materials such as, for example, thermally conductive adhesive tape materials commercially available from 3M Company (Saint Paul, Minn., USA). The thermal conductivity of the suitable PSA based material may be in a range from about 0.25 to about 10 m-K/W. The layer 380 may have a thickness, for example, in the range from about 0.5 to about 10 mils. The thermal interface material 380 can be disposed on one or both sides of the device to cover the electrodes by any suitable processes such as, for example, laminating, coating, etc.

In some embodiments, a thermally conductive plate can be disposed on the first or second side the thermoelectric device. The plate can be made of a flexible thermal-conductive material such as, for example, a metal film (e.g., an aluminum film). The TIM layer 380 can be positioned between the thermoelectric device and the thermo-conductive plate to enhance the heat exchange therebetween.

FIG. 4 is a schematic cross-sectional view of the flexible thermoelectric device 300 of FIG. 3E disposed on a curved surface, according to one embodiment. The flexible thermoelectric device 300 wraps around a tube 8. The slot openings 352 on the substrate 310 can help to remove tension or compression induced during the bending of the device 300.

Unless otherwise indicated, all numbers expressing quantities or ingredients, measurement of properties and so forth used in the specification and embodiments are to be understood as being modified in all instances by the term “about.” Accordingly, unless indicated to the contrary, the numerical parameters set forth in the foregoing specification and attached listing of embodiments can vary depending upon the desired properties sought to be obtained by those skilled in the art utilizing the teachings of the present disclosure. At the very least, and not as an attempt to limit the application of the doctrine of equivalents to the scope of the claimed embodiments, each numerical parameter should at least be construed in light of the number of reported significant digits and by applying ordinary rounding techniques.

Exemplary embodiments of the present disclosure may take on various modifications and alterations without departing from the spirit and scope of the present disclosure. Accordingly, it is to be understood that the embodiments of the present disclosure are not to be limited to the following described exemplary embodiments, but is to be controlled by the limitations set forth in the claims and any equivalents thereof

### Listing of Exemplary Embodiments

Exemplary embodiments are listed below. It is to be understood that any one of embodiments 1-12 and 13-20 can be combined.
Embodiment 1 is a thermoelectric device comprising:

a flexible substrate having opposite first and second sides, the flexible substrate extending along a longitudinal direction;

a first set of electrodes on the first side of the flexible substrate;

a second set of electrodes on the second side of the flexible substrate; and

an array of thermoelectric elements supported by the flexible substrate, the plurality of thermoelectric elements being electrically connected by the first set of electrodes on the first side and the second set of electrodes on the second side,

wherein the flexible substrate has an array of slot openings each extending along a cross direction substantially perpendicular to the longitudinal direction.
Embodiment 2 is the thermoelectric device of embodiment 1, wherein the array of slot openings is on the first side of the flexible substrate.
Embodiment 3 is the thermoelectric device of embodiment 1 or 2, wherein the array of slot openings is the second side of the flexible substrate.
Embodiment 4 is the thermoelectric device of any one of embodiments 1-3, wherein the flexible substrate includes via holes to receive the thermoelectric elements.
Embodiment 5 is the thermoelectric device of any one of embodiments 1-4, wherein the flexible substrate includes first and second portions laminated with each other, the first portion having the first set of electrodes disposed thereon, and the second portion having the first set of electrodes disposed thereon.
Embodiment 6 is the thermoelectric device of embodiment 5, wherein the first or second portion has a thickness from about 12.5 to about 125 micrometers.
Embodiment 7 is the thermoelectric device of any one of embodiments 1-6, wherein the flexible substrate includes polyimide, polyesters, liquid crystalline polymers, polyamides, thermoplastic polyimide, thermoplastic dielectric films, polytetrafluoroethylene, or perfluoroalkoxy alkane (PFA).
Embodiment 8 is the thermoelectric device of any one of embodiments 1-7, wherein the thermoelectric elements include n-type and p-type thermoelectric elements electrically connected in series.
Embodiment 9 is the thermoelectric device of any one of embodiments 1-8, wherein the flexible substrate includes a plurality of frames arranged along the longitudinal direction, each frame has the first set of electrodes and the second set of electrodes, the first sets are connected on the first side, and the second sets are connected on the second side.
Embodiment 10 is the thermoelectric device of embodiment 9, wherein each frame includes a plurality of first registration marks configured to align patterns on the opposite first and second sides of the substrate.
Embodiment 11 is the thermoelectric device of embodiment 10, wherein the first registration marks include through-holes.
Embodiment 12 is the thermoelectric cooler of embodiment 8, wherein each frame includes a plurality of second registration marks located adjacent to edges of the respective frames to align the frames along the longitudinal direction.
Embodiment 13 is a method of making a thermoelectric device on a moving web comprising:

providing a web path to move the web along a machine direction, the web having opposite first and second sides;

providing a first set of electrodes on the first side of the web;

creating an array of slots on the first surface of the web, each extending along a cross direction substantially perpendicular to the machine direction; and

providing a plurality of thermoelectric elements supported by the web, the plurality of thermoelectric elements being electrically connected by the first set of electrodes on the first side.
Embodiment 14 is the method of embodiment 13, wherein providing the first set of electrodes comprises providing an electrically conductive layer on the first side of the web, and creating a photoresist pattern thereon.
Embodiment 15 is the method of embodiment 13 or 14, wherein the photoresist pattern is created by a photolithography process.
Embodiment 16 is the method of embodiment 15, wherein the photolithography process includes providing a plurality of regions on the web arranged along the machine direction thereof, each region including a plurality of registration through holes configured to align patterns on the opposite first and second sides.
Embodiment 17 is the method of embodiment 15, wherein the photolithography process further includes developing a plurality of photoresist pattern frames on the web, the frames being aligned along the machine direction.
Embodiment 18 is the method of embodiment 17, wherein plurality of photoresist pattern frames each includes registration marks configured to align with each other.
Embodiment 19 is the method of any one of embodiments 13-18, further comprising creating via holes on the second side of the web to expose at least a portion of a rear surface of the patterned electrode on the first side.
Embodiment 20 is the method of embodiment 19, wherein at least a portion of the plurality of thermoelectric elements is received by the via holes.

Reference throughout this specification to “one embodiment,” “certain embodiments,” “one or more embodiments,” or “an embodiment,” whether or not including the term “exemplary” preceding the term “embodiment,” means that a particular feature, structure, material, or characteristic described in connection with the embodiment is included in at least one embodiment of the certain exemplary embodiments of the present disclosure. Thus, the appearances of the phrases such as “in one or more embodiments,” “in certain embodiments,” “in one embodiment,” or “in an embodiment” in various places throughout this specification are not necessarily referring to the same embodiment of the certain exemplary embodiments of the present disclosure. Furthermore, the particular features, structures, materials, or characteristics may be combined in any suitable manner in one or more embodiments.

While the specification has described in detail certain exemplary embodiments, it will be appreciated that those skilled in the art, upon attaining an understanding of the foregoing, may readily conceive of alterations to, variations of, and equivalents to these embodiments. Accordingly, it should be understood that this disclosure is not to be unduly limited to the illustrative embodiments set forth hereinabove. In particular, as used herein, the recitation of numerical ranges by endpoints is intended to include all numbers subsumed within that range (e.g., 1 to 5 includes 1, 1.5, 2, 2.75, 3, 3.80, 4, and 5). In addition, all numbers used herein are assumed to be modified by the term “about.” Furthermore, various exemplary embodiments have been described. These and other embodiments are within the scope of the following claims.

1. A thermoelectric device comprising:
a flexible substrate having opposite first and second sides, the flexible substrate extending along a longitudinal direction;
a first set of electrodes on the first side of the flexible substrate;
a second set of electrodes on the second side of the flexible substrate; and
an array of thermoelectric elements supported by the flexible substrate, the plurality of thermoelectric elements being electrically connected by the first set of electrodes on the first side and the second set of electrodes on the second side,
wherein the flexible substrate has an array of slot openings each extending along a cross direction substantially perpendicular to the longitudinal direction.

2. The thermoelectric device of claim 1, wherein the array of slot openings is on the first side of the flexible substrate.

3. The thermoelectric device of claim 1, wherein the array of slot openings is the second side of the flexible substrate.

4. The thermoelectric device of claim 1, wherein the flexible substrate includes via holes to receive the thermoelectric elements.

5. The thermoelectric device of claim 1, wherein the flexible substrate includes first and second portions laminated with each other, the first portion having the first set of electrodes disposed thereon, and the second portion having the first set of electrodes disposed thereon.

6. The thermoelectric device of claim 5, wherein the first or second portion has a thickness from about 12.5 to about 125 micrometers.

7. The thermoelectric device of claim 1, wherein the flexible substrate includes polyimide.

8. The thermoelectric device of claim 1, wherein the thermoelectric elements include n-type and p-type thermoelectric elements electrically connected in series.

9. The thermoelectric cooler of claim 1, wherein the flexible substrate includes a plurality of frames arranged along the longitudinal direction, each frame has the first set of electrodes and the second set of electrodes, the first sets are connected on the first side, and the second sets are connected on the second side.

10. The thermoelectric cooler of claim 9, wherein each frame includes a plurality of first registration marks configured to align patterns on the opposite first and second sides of the substrate.

11. The thermoelectric cooler of claim 10, wherein the first registration marks include through-holes.

12. The thermoelectric cooler of claim 9, wherein each frame includes a plurality of second registration marks located adjacent to edges of the respective frames to align the frames along the longitudinal direction.

13. A method of making a thermoelectric device on a moving web comprising:
providing a web path to move the web along a machine direction, the web having opposite first and second sides;
providing a first set of electrodes on the first side of the web;
creating an array of slots on the first surface of the web, each extending along a cross direction substantially perpendicular to the machine direction; and
providing a plurality of thermoelectric elements supported by the web, the plurality of thermoelectric elements being electrically connected by the first set of electrodes on the first side.

14. The method of claim 13, wherein providing the first set of electrodes comprises providing an electrically conductive layer on the first side of the web, and creating a photoresist pattern thereon.

15. The method of claim 13, wherein the photoresist pattern is created by a photolithography process.

16. The method of claim 15, wherein the photolithography process includes providing a plurality of regions on the web arranged along the machine direction thereof, each region including a plurality of registration through-holes configured to align patterns on the opposite first and second sides.

17. The method of claim 15, wherein the photolithography process further includes sequentially developing a plurality of photoresist pattern frames on the web, the frames being aligned along the machine direction.

18. The method of claim 17, wherein plurality of photoresist pattern frames each includes registration marks configured to align with each other.

19. The method of claim 13, further comprising creating via holes on the second side of the web to expose at least a portion of a rear surface of the patterned electrode on the first side.

20. The method of claim 19, wherein at least a portion of the plurality of thermoelectric elements is received by the via holes.
